(19) United States
(12) Patent Application Publication
(10) Pub. No.: US 2006/0061239 A1
(43) Pub. Date: Mar. 23, 2006

(54) Automatic temperature control unit

(76) Inventor: Michael D. Davis, Richmond, VA (US)

Correspondence Address: GOODMAN, ALLEN & FILETTI PLLC, 4501 HIGHWOODS PARKWAY, SUITE 210, GLEN ALLEN, VA, 23060, US

(21) Appl. No.: 11/228,674

(22) Filed: Sep. 16, 2005

Related U.S. Application Data
(60) Provisional application No. 60/610,719, filed on Sep. 17, 2004.

(51) Int. Cl. H01L 41/18

(52) U.S. Cl. 310/346

(57) ABSTRACT

The present invention presents a temperature driven control apparatus that can be used to make mechanical adjustments to a variety of devices and machines. In one embodiment, the apparatus provides a means of regulating the cooking temperature of a gas burner while such burner is used to heat a liquid mixture. The apparatus consists primarily of a temperature probe, a controlling circuit and a servo motor. Accordingly, the apparatus is able to monitor the temperature of a liquid or fluid and execute mechanical adjustments to the manual controls of a heating apparatus in order to keep the liquid or fluid at a desired, pre-determined temperature.

### CROSS-REFERENCE TO RELATED APPLICATIONS

This application claims priority from U.S. Provisional Application 60/610,719.

### BRIEF DESCRIPTION OF THE DRAWINGS

FIG. 1 is an exterior view of front of the encasement.

FIG. 2 is a exterior view of rear of the encasement.

FIG. 3 is an exterior view of the underside of the encasement.

FIG. 4 is an exploded view of the device.

FIG. 5 is a schematic of one embodiment of the control circuit.

### SUMMARY AND OBJECTS OF THE INVENTION

The invention discloses a novel and efficient control mechanism for any system that is related to the temperature of a liquid or fluid volume. In its most basic embodiment, the instant invention discloses a device that serves to monitor the temperature of a liquid or fluid that is being heated on a domestic heating appliance, e.g., a gas range, and automatically make mechanical adjustments to the control knob of the heating appliance in order to maintain the desired temperature of the material being heated. Specifically, in the foregoing embodiment, the device uses a temperature measuring integrated circuit to report temperature changes via voltage output. A control circuit then compares the voltage output, and consequently the temperature, with a static value. The control chip thus has the ability to determine if an adjustment of the control knob of the heating appliance is necessary, and, if so, make the adjustment accordingly.

An example of the benefits of such a device can be demonstrated in the area of home beer brewing. As it stands today, it is difficult for the average home brewer to maintain adequate temperature control, particularly during the step known as the mashing process. The mashing process is the step whereby the brewer is required to submerge the grain in water that has a temperature of approximately 150 degrees Fahrenheit for over thirty minutes. Without a specialized temperature controlled boiler or similar unit, the home brewer is forced to monitor the temperature manually in order to maintain the required temperature. This is rather difficult to accomplish without a substantial investment of time and effort and thus, in most cases, such manual monitoring results in errors and ultimately an improper mash. This invention, among other objects, is intended to allow brewers to use their existing heating methods and cookware by monitoring the temperature of the brew and automatically manipulating the controls of a heating unit. Since most such home brewers brew on their kitchen stove, this invention provides a generic means for controlling a variety of stoves and burners.

Accordingly, it is an object of the invention to present a mechanical control unit that may be used in a variety of applications, under any circumstances, that require temperature dependant adjustments. It is further an object of the invention to present a simple and effective yet inexpensive device to accomplish the foregoing goal. It is an additional object of the invention to specifically provide an automated means of temperature control that is compatible with both domestic cooking and the domestic brewing of alcoholic beverages.

### DETAILED DESCRIPTION OF THE PREFERRED EMBODIMENT

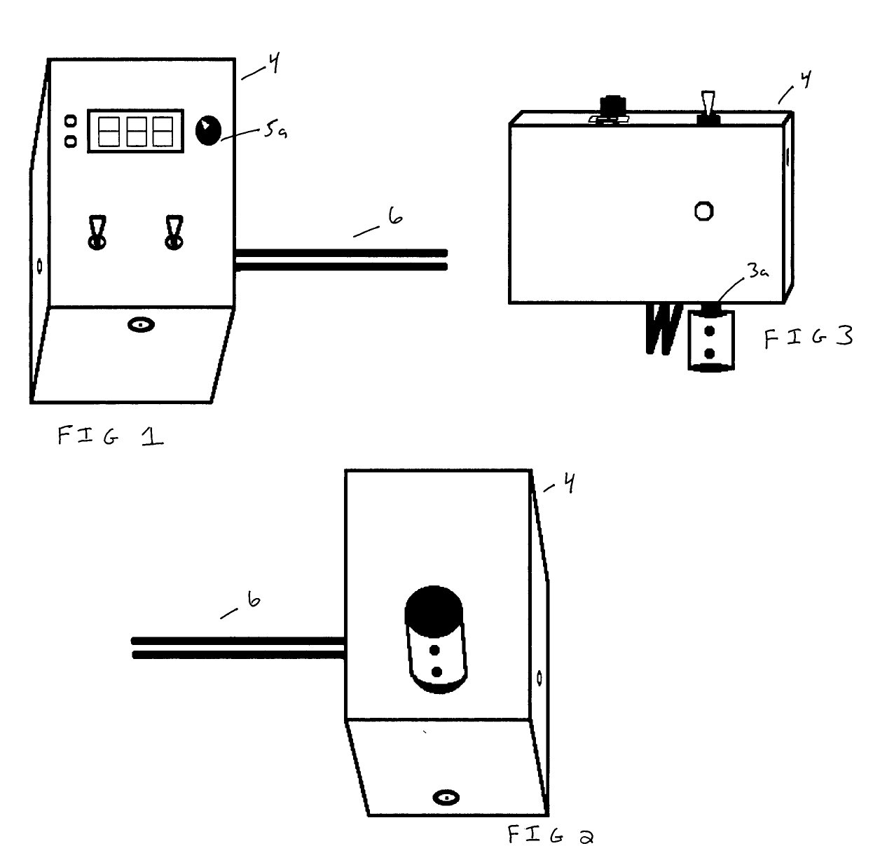

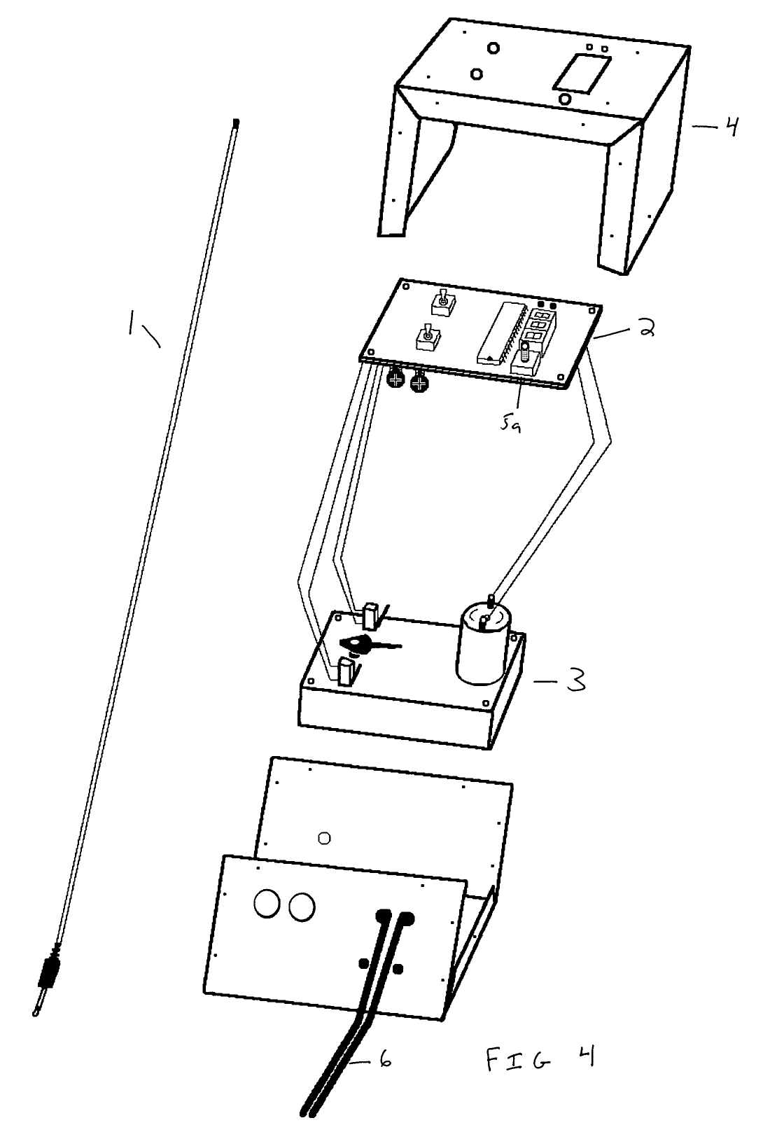

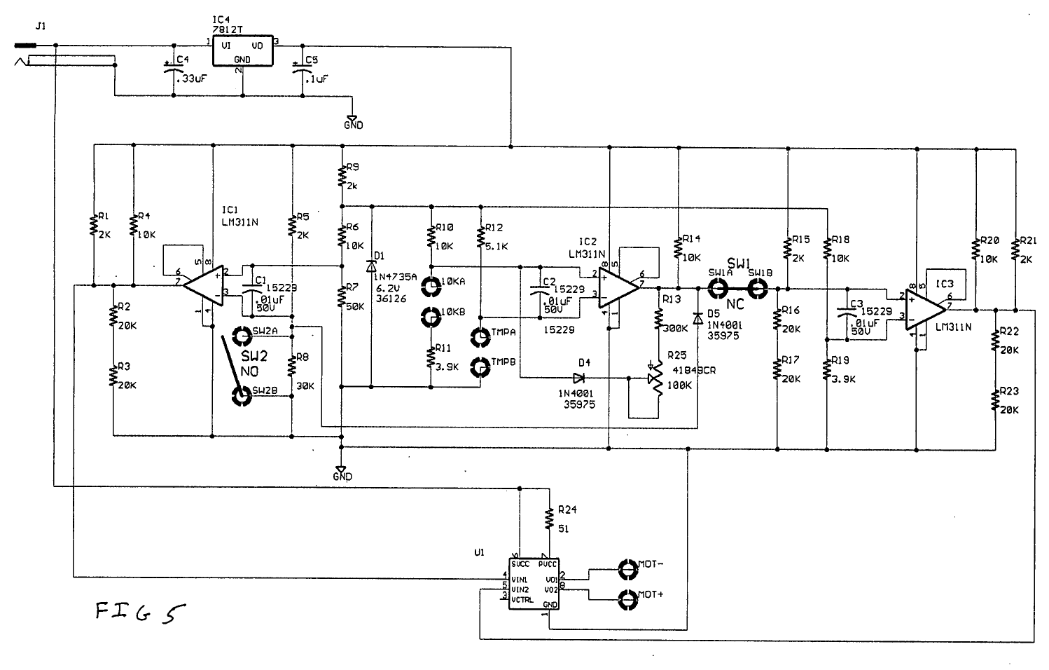

Referring generally to FIGS. 1-4, the primary embodiment of the device includes temperature sensor assembly 1, a control circuit 2, a DC motor 3, and a power source with associated equipment (not shown). In its most basic embodiment, the instant invention serves to monitor the temperature of a liquid or fluid that is being heated/cooked on a gas or electric cooking range, and automatically make mechanical adjustments to the control knob of the cooking range in order to maintain the desired temperature in the liquid or fluid. In such an embodiment, the control circuit 2 and DC motor 3 are mounted in a casing box 4 and the temperature sensor assembly 1 is attached thereto.

The temperature sensor assembly 1 can be constructed through the use of a temperature measuring integrated circuit such as the LM335AZ obtainable from Jameco® Electronics at www.jameco.com. This integrated circuit can report temperature changes by controlling its voltage output with such output being directly proportionate to the absolute temperature of a liquid. The circuit is attached to two or three wires (depending on the requirements of the circuit used in a particular application) which must be of sufficient length to allow the circuit to be submerged in the liquid or fluid that is to be monitored. Due to the fact that the circuit and accompanying wiring may be submerged in high temperature, and even potentially corrosive, liquid environments depending on the application, the circuit can be covered with a liquid and/or heat resistant coating such as heat shrink tubing. The temperature sensor assembly 1 is then connected to the control circuit 2 that sits within the casing 4.

The control circuit 2 mounted on a printed circuit board acts as the driver for the motor. The control circuit 2 relies upon a comparator in order to compare the voltage input of a static value with the voltage input from the temperature sensor assembly 3. The static value is to be set through the use of a potentiometer 5, such as the 10 k potentiometer as seen in FIG. 5, which is accessible for user adjustment at point 5a. The static value correlates to a particular temperature allowing the user to set the desired temperature goal of the fluid or liquid. Once activated, the control circuit 2 will generate either a high voltage output or a low voltage output depending on whether the input voltage from the temperature sensor is higher or lower than the user defined value set by the potentiometer.

As seen in FIG. 5, the comparator can be constructed through the use of operational amplifiers. However, it will also be recognized that a dedicated comparator chip may be used in place of the operational amplifiers to accomplish the same effect. An LED (Light Emitting Diode) or other such visual display can also be incorporated into the control circuit, and calibrated with the potentiometer, in order to provide greater feedback for a user of the invention.

The ultimate adjustment of a mechanical control on a heating apparatus is carried out by a servo unit. The servo unit for the manipulation of the cooking range dial may be constructed by connecting the spindle 3a of a DC motor 3 to the spindle that is present under most conventional cooking range dials. An additional output shaft, coupling, mounting bracket or mounting assembly may be attached to the motor as may required in order to properly attach the motor 3 to a particular spindle or control knob that is to be actuated. One of the primary advantages of the instant invention is that it can be easily retrofitted in a variety of applications. In the case of its use with home heating appliances, it is, in essence, a universal control, as the spindle 3a can be replaced with whatever size or type coupling is necessary to mount the device on a particular heating appliance.

The DC motor 3 is connected to the control circuit such that the motor behaves as a servo. As a result, the motor 3 will rotate the output shaft in an appropriate direction based upon the level of voltage received from the control circuit 2. The direction of rotation determines whether the device raises or lowers the level of heat output by the cooking range. The range of motion of the rotation of the motors may be limited or otherwise controlled through the use of electrical contacts or switches that are incorporated so as to cause the motor control unit to cease action upon reaching certain limits. In addition, a user accessible switch may be incorporated into the control circuit so as to limit travel in a particular direction.

The motor need not be exclusively designed to rotate a knob or dial. The motor could be configured to operate whatever such control may be necessary based upon the temperature difference determined by the control circuit. Indeed, the control circuit need not even be attached to a motor but rather could be connected to a solenoid type unit for toggling a switch or such other actuating devices for accomplishing the required task.

The casing 4 is connected via the attachment arm 6 to another cooking range dial spindle, if available, for added leverage during operation. The attachment arm 6 may be of varying design and dimensions in order to accommodate different models of cooking ranges or other mounting conditions.

The control circuit 2 and the DC motor 3 will normally be powered by a commercially supplied power source through a well-known AC/DC adaptor. It will be noted that the control circuit reflected in FIG. 5 includes circuitry to regulate the input DC voltage to provide a constant 12V, however, this may not be necessary depending on the power source and the implementation.

While the invention has been described in reference to certain preferred embodiments, it will be readily apparent to one of ordinary skill in the art that certain modifications or variations may be made to the system without departing from the scope of invention claimed below and described in the foregoing specification.

I claim:

1. A temperature control unit for a fluid heating apparatus comprising:
A temperature monitoring unit positioned so as to monitor the temperature of said fluid volume;
A means for comparing the temperature of said fluid volume with a predetermined value; and
A means for mechanically adjusting the heat output of the heating apparatus;
Whereby the heat output of the heating apparatus may be automatically adjusted in order to maintain a predetermined fluid volume temperature:

2. The device as in claim 1 wherein said temperature monitoring unit comprises a temperature probe.

3. The device as in claim 2 wherein at least a portion of said temperature probe is composed of an environmentally resistant material.

4. The device as in claim 2 wherein said temperature probe further comprises an integrated circuit temperature sensor having a plurality of output wires.

5. The device as in claim 4 wherein at least a portion of said temperature probe is covered with an environmentally resistant coating.

6. The device as in claim 5 wherein said environmentally resistant coating further comprises heat shrink tubing.

7. The device as in claim I wherein said means for comparing the temperature of said fluid volume with a predetermined value comprises a comparator.

8. The device as in claim 7 wherein said comparator further comprises at least one operational amplifier.

9. The device as in claim 8 wherein said comparator further comprises at least three operational amplifiers, a plurality of resistors, a plurality of capacitive devices and a potentiometer.

10. The device as in claim 1 wherein said means for adjusting the heat output comprises a servo motor for actuating a manual control on said heating apparatus.

11. The device as in claim 10 wherein said servo motor is a DC motor.

12. The device as in claim 1 further comprising a means for securing the temperature control unit to the heating apparatus.

13. The device as in claim 1 further comprising a mounting bracket attached to said temperature control unit whereby said bracket may be secured to a spindle control of said heating apparatus.

14. The device in claim 1 wherein said heating apparatus comprises a cooking appliance.

15. The device as in claim 14 wherein said cooking appliance is a stove.

16. A universal temperature control unit for a stove comprising:
A temperature monitoring device;
An elctromechanical device in electrical communication with said temperature monitoring device; said electromechanical device being operably connected to a spindle of said stove;
Whereby said electromechanical device rotates said spindle as a function of the temperature obtained by said temperature monitoring device.

17. A temperature dependant control unit for the automatic control of a process involving a volume of fluid comprising:
A temperature monitoring unit positioned so as to monitor the temperature of said volume of fluid;
A means for comparing the temperature of said volume of fluid with a predetermined value; said means for comparing said temperature and said predetermined value comprising a comparator circuit having at least two variable resistors; and
A means for mechanically adjusting a parameter of said process based upon the comparison of said temperatures.

18. A temperature sensitive electromechanical actuation device comprising:
A servo motor;
An output shaft attached to said servo motor;
A temperature sensor; and
A controller circuit connect to said temperature sensor; said controller circuit comprising a comparator and a potentiometer; said controller circuit being further connected to said servo motor;
Whereby said controller circuit operates said servo motor to rotate said output shaft when the value returned by said temperature sensor varies beyond a predetermined range.

19. A retrofittable control unit for a heating or cooling apparatus comprising:
A temperature sensor;
A control circuit connected to said temperature sensor; said control circuit comprising a comparator means; and
A mechanical actuator in connection with said control circuit and in contact with a manual control element of said heating or cooling apparatus;
Whereby said control circuit operates said actuator based on the results outputted by said temperature sensor and said actuator manipulates said control element accordingly.

20. An independent and retrofittable temperature control unit for controlling a home heating apparatus comprising:
Temperature monitoring circuitry;
A temperature monitoring probe connected to said temperature monitoring circuitry; and
An electromechanical device under the control of said temperature monitoring circuitry; said electromechanical device being used to effect adjustments on said heating apparatus.
